(19) United States
(12) Patent Application Publication
(10) Pub. No.: US 2022/0310484 A1
(43) Pub. Date: Sep. 29, 2022

(54) SEMICONDUCTOR STRUCTURE AND FABRICATION METHOD THEREOF

(71) Applicant: CHANGXIN MEMORY TECHNOLOGIES, INC., Hefei (CN)

(72) Inventors: Nianwang YANG, Hefei (CN); Mengmeng WANG, Hefei (CN)

(21) Appl. No.: 17/480,136

(22) Filed: Sep. 20, 2021

Related U.S. Application Data
(63) Continuation of application No. PCT/CN2021/111069, filed on Aug. 6, 2021.

(30) Foreign Application Priority Data
Mar. 24, 2021 (CN) 202110315842.6

(51) Int. Cl. H01L 23/48; H01L 21/768; H01L 23/31

(52) U.S. Cl. CPC H01L 23/481; H01L 21/76832; H01L 23/3192

(57) ABSTRACT

Embodiments relate to a semiconductor structure and a fabrication method thereof. The semiconductor structure includes: a substrate, the substrate including a peripheral region and a chip region; a first dielectric layer positioned on the peripheral region and the chip region of the substrate; and a protective structure and a functional structure respectively positioned in the first dielectric layer on the peripheral region and in the first dielectric layer on the chip region. The protective structure includes a first subportion, a second subportion and a third subportion stacked in sequence, and the functional structure includes a fourth subportion and a fifth subportion stacked in sequence. A total height of the first subportion, the second subportion and the third subportion is equal to a total height of the fourth subportion and the fifth subportion.

### CROSS-REFERENCE TO RELATED APPLICATION

This application is a continuation of PCT/CN2021/111069, filed on Aug. 6, 2021, which claims priority to Chinese Patent Application No. 2021103158426 titled “SEMICONDUCTOR STRUCTURE AND FABRICATION METHOD THEREOF” and filed to the State Intellectual Property Office on Mar. 24, 2021, the entire contents of which are incorporated herein by reference.

### TECHNICAL FIELD

The present disclosure relates to the field of semiconductor fabrication technology, and more particularly, to a semiconductor structure and a fabrication method thereof.

### BACKGROUND

When a wafer is diced, a dicing mode of a dicing street may generate a certain mechanical stress on front and back surfaces of the wafer, which may cause chippings at an edge of a chip. The problem of chippings may reduce a mechanical strength of the chip, and an initial chip edge crack may be further spread in later packaging process or in the use of chip products, which may likely cause cracking of the chip, thus leading to failure of electrical properties of the chip. To protect internal circuits of the chip, prevent scratch damage, and improve reliability of the chip, a semiconductor structure such as a seal ring generally is designed at the periphery of the chip. Moreover, the seal ring structure also is capable of resisting gas and liquid erosion, which can prevent water vapor or other chemical contamination sources from permeating the chip to avoid causing damage to the chip.

At present, as sizes of semiconductor devices continue to decrease, roles of the seal ring at the periphery of the chip are becoming more and more important. However, the existing sealing rings are unable to provide better protection to the chip due to their poor stability and smaller interception area, and can no longer meet the requirements for protection of the chip.

### SUMMARY

According to various embodiments of the present disclosure, a semiconductor structure and a fabrication method thereof are provided.

The present disclosure provides a semiconductor structure, comprising:

a substrate comprising a peripheral region and a chip region;

a first dielectric layer positioned on the peripheral region and the chip region of the substrate; and

a protective structure and a functional structure respectively positioned in the first dielectric layer on the peripheral region and in the first dielectric layer on the chip region.

The protective structure comprises a first subportion, a second subportion and a third subportion stacked in sequence. The functional structure comprises a fourth subportion and a fifth subportion stacked in sequence. A total height of the first subportion, the second subportion and the third subportion is equal to a total height of the fourth subportion and the fifth subportion.

The present disclosure also provides a method for fabricating a semiconductor structure, wherein the method includes following steps:

providing a substrate comprising a peripheral region and a chip region;

forming a first dielectric layer on the peripheral region and the chip region of the substrate; and

forming a protective structure and a functional structure respectively in the first dielectric layer on the peripheral region and in the first dielectric layer on the chip region.

The protective structure comprises a first subportion, a second subportion and a third subportion stacked in sequence. The functional structure comprises a fourth subportion and a fifth subportion stacked in sequence. A total height of the first subportion, the second subportion and the third subportion is equal to a total height of the fourth subportion and the fifth subportion.

### BRIEF DESCRIPTION OF THE DRAWINGS

To describe the technical solutions in the embodiments of the present disclosure or the existing technologies more clearly, the accompanying drawings required for describing the embodiments or the existing technologies will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a flow diagram of a method for fabricating a semiconductor structure according to one embodiment of the present disclosure;

FIG. 2 is a schematic cross-sectional view of a bottom-layer dielectric layer according to one embodiment of the present disclosure;

FIG. 3 is a schematic cross-sectional view of a structure obtained in Step S2 of a method for fabricating a semiconductor structure according to one embodiment of the present disclosure;

FIG. 4 is a flow diagram of Step S3 in a method for fabricating a semiconductor structure according to one embodiment of the present disclosure;

FIG. 5 is a schematic cross-sectional view of a structure obtained in Step S32 of a method for fabricating a semiconductor structure according to one embodiment of the present disclosure;

FIG. 6 is a schematic cross-sectional view of a structure obtained in Step S35 of a method for fabricating a semiconductor structure according to one embodiment of the present disclosure;

FIG. 7 is a schematic cross-sectional view of a structure obtained in Step S38 of a method for fabricating a semiconductor structure according to one embodiment of the present disclosure;

FIG. 8 is a schematic cross-sectional view of a structure obtained in Step S3 of a method for fabricating a semiconductor structure according to one embodiment of the present disclosure, and also is a schematic diagram of a semiconductor structure according to one embodiment of the present disclosure;

FIG. 9 is a schematic cross-sectional view of a structure obtained in Step S4 of a method for fabricating a semiconductor structure according to one embodiment of the present disclosure;

FIG. 10 is a schematic cross-sectional view of a structure obtained in Step S6 of a method for fabricating a semiconductor structure according to one embodiment of the present disclosure;

FIG. 11 is a schematic cross-sectional view of a structure obtained in Step S7 of a method for fabricating a semiconductor structure according to one embodiment of the present disclosure;

FIG. 12 is a schematic cross-sectional view of a structure obtained in Step S8 of a method for fabricating a semiconductor structure according to one embodiment of the present disclosure;

FIG. 13 is a schematic cross-sectional view of a structure obtained in Step S9 of a method for fabricating a semiconductor structure according to one embodiment of the present disclosure; and

FIG. 14 is a schematic cross-sectional view of a structure obtained in Step S10 of a method for fabricating a semiconductor structure according to one embodiment of the present disclosure, and also is a schematic diagram of a semiconductor structure according to one embodiment of the present disclosure.

### DETAILED DESCRIPTION

For ease of understanding the present disclosure, the present disclosure will be described more fully hereinafter with reference to the accompanying drawings. Some embodiments of the present disclosure are provided in the accompanying drawings. The present disclosure may, however, be embodied in many different forms and should not be limited to the embodiments set forth herein. Rather, these embodiments are provided so that the present disclosure will be more thorough and complete.

Unless otherwise defined, all technical and scientific terms employed herein have the same meaning as commonly understood by one of ordinary skill in the art to which the present disclosure belongs. The terms employed in the specification of the present disclosure are merely for the purpose of describing some embodiments and are not intended for limiting the present disclosure.

It should be understood that when an element or layer is referred to as being “on”, “adjacent to”, “connected to” or “coupled to” other elements or layers, it may be directly on, adjacent to, connected or coupled to the other elements or layers, or intervening elements or layers may be present. In contrast, when an element is referred to as being “directly on”, “directly adjacent to”, “directly connected to” or “directly coupled to” other elements or layers, there are no intervening elements or layers present. It should be understood that although the terms first, second, third, etc. may be employed to describe various elements, components, regions, layers, doping types and/or sections, these elements, components, regions, layers, doping types and/or sections should not be limited by these terms. These terms are only employed to distinguish one element, component, region, layer, doping type, or section from another element, component, region, layer, doping type, or section. Thus, without departing from the teachings of the present disclosure, a first element, component, region, layer, doping type or portion discussed below may be represented as a second element, component, region, layer or portion. For example, a first doping type may be a second doping type, and similarly, the second doping type may be the first doping type. Furthermore, the first doping type and the second doping type may be different doping types. For example, the first doping type may be a P type and the second doping type may be an N type, or the first doping type may be the N type and the second doping type may be the P type.

Spatially relative terms such as “below”, “under”, “lower”, “beneath”, “above”, “upper” and the like may be used herein to describe relationships between one element or feature as shown in the figures and another element(s) or feature(s). It should be understood that the spatially relative terms may be intended to encompass different orientations of a device in use or operation in addition to the orientation depicted in the figures. For example, if the device in the figures is turned over, elements or features described as “under”, “beneath” or “below” other elements would then be oriented “above” the other elements or features. Thus, the example term “under”, “below” or “beneath” may encompass both an orientation of above and below. In addition, the device may also be otherwise oriented (for example, rotated 90 degrees or at other orientations) and the spatially descriptors used herein should be interpreted accordingly.

As used herein, the singular forms of “a”, “one” and “said/the” are also intended to include plural forms, unless the context clearly indicates otherwise. It should also be understood that the terms “comprising” and/or “including”, when used in this specification, may determine the presence of the described features, integers, steps, operations, elements and/or components, but do not preclude the presence or addition of one or more other features, integers, steps, operations, elements, components, and/or groups thereof. Meanwhile, as used herein, the term “and/or” includes any and all combinations of related listed items.

Embodiments of the present disclosure are described herein with reference to cross-sectional illustrations serving as schematic illustrations of embodiments (and intermediate structures) of the present disclosure. As such, variations from the shapes of the illustrations as a result, for example, of manufacturing techniques and/or tolerances, may be expected. Thus, embodiments of the present disclosure should not be construed as being limited to particular shapes of regions illustrated herein but may include deviations in shapes that result, for example, from fabrication technologies. Thus, regions illustrated in the figures are schematic in nature and their shapes do not necessarily illustrate the actual shape of a region of the device and do not limit the scope of the present disclosure.

With reference to FIG. 1, an embodiment of the present disclosure provides a method for fabricating a semiconductor structure, wherein the method includes following steps:

S1: providing a substrate (not shown in the figure), which includes a peripheral region and a chip region;

S2: forming a first dielectric layer 2 on the peripheral region and the chip region of the substrate; and

S3: forming a protective structure 21 and a functional structure 22 in the first dielectric layer 2 on the peripheral region and in the first dielectric layer 2 on the chip region, respectively.

The protective structure 21 comprises a first subportion 211, a second subportion 212 and a third subportion 213 stacked in sequence. The functional structure 22 comprises a fourth subportion 224 and a fifth subportion 225 stacked in sequence. A total height of the first subportion 211, the second subportion 212 and the third subportion 213 is equal to a total height of the fourth subportion 224 and the fifth subportion 225.

The semiconductor structure formed by means of the method for fabricating a semiconductor structure provided in the above embodiment has a more stable structure, has a larger interception area, provides better protection to the chip, and has a simpler technological process.

In one embodiment, the substrate may include, but is not limited to, a silicon substrate. In other embodiments, the substrate may also be a gallium nitride substrate, an indium phosphide substrate, or a sapphire substrate, etc.

In one embodiment, before Step S2, the method may include:

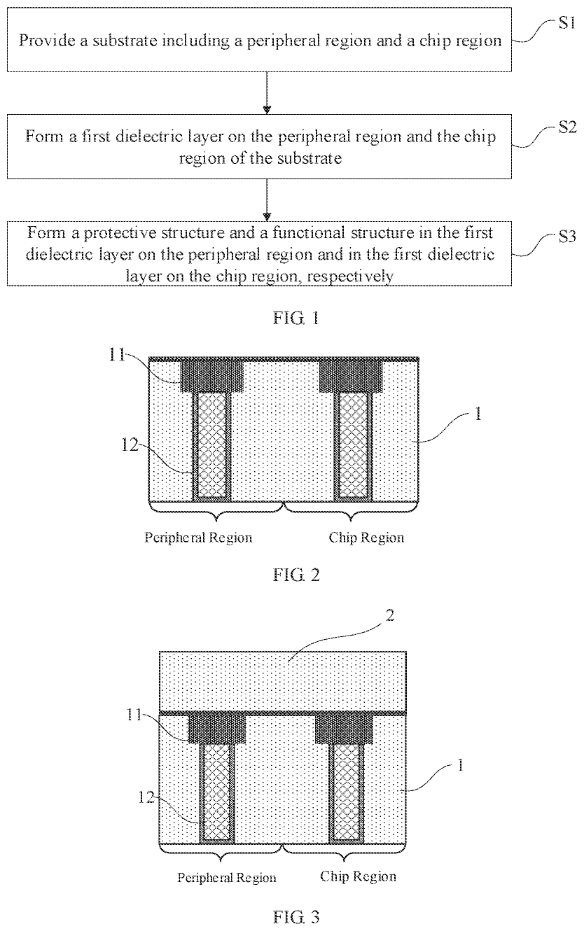

forming a bottom-layer dielectric layer 1 on the peripheral region and the chip region of the substrate, as shown in FIG. 2.

It is to be noted that the bottom-layer dielectric layer 1 may be formed on the substrate, as shown in FIG. 2, a bottom-layer metal layer 11 and an interconnection structure 12 are formed in the bottom-layer dielectric layer 1. In some embodiments, in one embodiment, a through hole is respectively formed in the peripheral region and the chip region of the bottom-layer dielectric layer 1, and the interconnection structure 12 and the bottom-layer metal layer 11 are stacked sequentially from bottom to top in the through hole.

In one embodiment, the interconnection structure 12 may be a single-layer structure, a stacked-layer structure or other structure, but the interconnection structure 12 in this embodiment is not limited thereto. In one embodiment, a material of the interconnection structure 12 may comprise one or more of titanium, titanium nitride, or tungsten, etc. This embodiment does not limit the material of the interconnection structure 12. In one embodiment, the interconnection structure 12 includes a conductive metal and a barrier layer, wherein the conductive metal may include, but is not limited to, tungsten, ruthenium, and the like, and the barrier layer may include, but is not limited to, titanium nitride, titanium, and the like.

In the above embodiment, Step S2 may include:

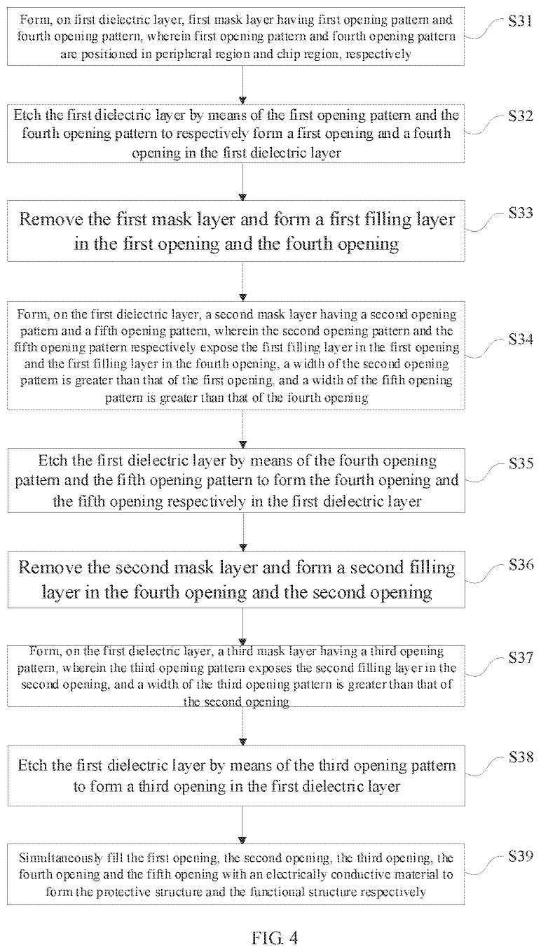

forming a first dielectric layer 2 on the peripheral region and the chip region of the bottom-layer dielectric layer 1, as shown in FIG. 3.

For Step S3, as shown in FIG. 4, in one embodiment, Step S3 may include following steps:

S31: forming, on the first dielectric layer 2, a first mask layer having a first opening pattern and a fourth opening pattern, wherein the first opening pattern and the fourth opening pattern are positioned in the peripheral region and the chip region, respectively;

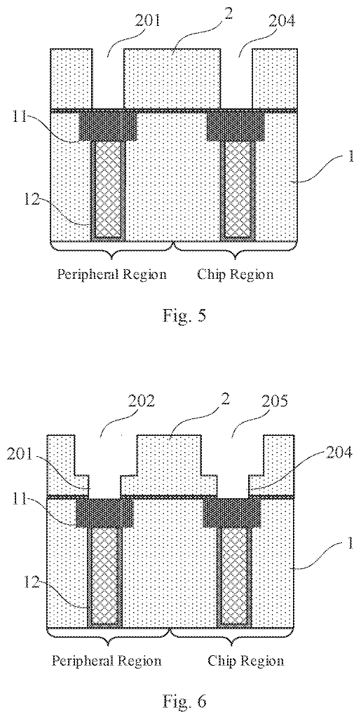

S32: etching the first dielectric layer 2 by means of the first opening pattern and the fourth opening pattern to respectively form a first opening 201 and a fourth opening 204 in the first dielectric layer 2, as shown in FIG. 5;

S33: removing the first mask layer and forming a first filling layer in the first opening 201 and the fourth opening 204;

S34: forming, on the first dielectric layer 2, a second mask layer having a second opening pattern and a fifth opening pattern, wherein the second opening pattern and the fifth opening pattern respectively expose the first filling layer in the first opening 201 and the first filling layer in the fourth opening 204, a width of the second opening pattern is greater than that of the first opening 201, and a width of the fifth opening pattern is greater than that of the fourth opening 204;

S35: etching the first dielectric layer 2 by means of the second opening pattern and the fifth opening pattern to form the second opening 202 and the fifth opening 205 respectively in the first dielectric layer 2, as shown in FIG. 6;

S36: removing the second mask layer and forming a second filling layer in the second opening 202 and the fifth opening 205;

S37: forming, on the first dielectric layer 2, a third mask layer having a third opening pattern, wherein the third opening pattern exposes the second filling layer in the second opening 202, and a width of the third opening pattern is greater than that of the second opening 202;

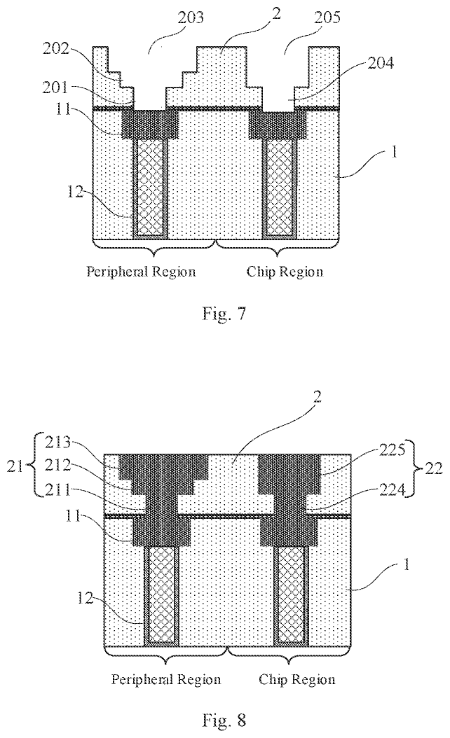

S38: etching the first dielectric layer 2 by means of the third opening pattern to form a third opening 203 in the first dielectric layer 2, as shown in FIG. 7; and

S39: simultaneously filling the first opening 201, the second opening 202, the third opening 203, the fourth opening 204 and the fifth opening 205 with an electrically conductive material to form the protective structure 21 and the functional structure 22 respectively, as shown in FIG. 8.

In one embodiment, the width of the first opening 201 is the same as that of the fourth opening 204, and the width of the second opening 202 is the same as that of the fifth opening 205.

Further, in one embodiment, an opening depth of the first opening 201 is the same as that of the fourth opening 204, and an opening depth of the second opening 202 is the same as that of the fifth opening 205.

In one embodiment, the opening depth of the first opening 201 is greater than that of the second opening 202, and the opening depth of the second opening 202 is greater than that of the third opening 203.

In one embodiment, the width of the first opening 201 is less than that of the second opening 202, the width of the second opening 202 is less than that of the third opening 203, and the width of the fourth opening 204 is less than that of the fifth opening 205.

In one embodiment, a total depth of the first opening 201, the second opening 202 and the third opening 203 is the same as a total depth of the fourth opening 204 and the fifth opening 205.

The electrically conductive material in the first opening 201 is the first subportion 211, the electrically conductive material in the second opening 202 is the second subportion 212, the electrically conductive material in the third opening 203 is the third subportion 213, the electrically conductive material in the fourth opening 204 is the fourth subportion 224, and the electrically conductive material in the fifth opening 205 is the fifth subportion 225.

In some embodiments, in one embodiment, the material of the protective structure 21 may include, but is not limited to, copper.

In some embodiments, the electrically conductive material may be copper, and an initial copper layer is formed simultaneously, by means of electroplating, in the first opening 201, the second opening 202, the third opening 203, the fourth opening 204, the fifth opening 205, and the first dielectric layer 2. Next, the initial copper layer above the first dielectric layer 2 is removed by means of chemical mechanical grinding to form the protective structure 21 and the functional structure 22 respectively. as shown in FIG. 8. The protective structure 21 may be formed separately in a copper-metal interconnection layer to enhance the protective effect of a copper-metal protection ring while saving production costs.

In one embodiment, the first dielectric layer 2 formed is a single-layer structure, and the protective structure 21 formed includes N subportions stacked sequentially, wherein N is an integer greater than 3.

In one embodiment, the first dielectric layer 2 may be a single-layer structure or a stacked-layer structure, and the structure of the first dielectric layer 2 in this embodiment is not limited thereto. In some embodiments, in one embodiment, the first dielectric layer 2 may be a silicon nitride layer and a silicon oxide layer stacked sequentially from bottom to top, and the protective structure 21 formed is positioned in the silicon oxide layer.

The semiconductor structure formed by means of the method for fabricating a semiconductor structure provided in the above embodiment has more subportions, which increases its interception area and further enhances the protection of this structure for the chip.

In one embodiment, widths of the N subportions stacked in sequence are sequentially increased.

The semiconductor structure formed by means of the method for fabricating a semiconductor structure provided in the above embodiment has N subportions stacked in sequence, and the widths of the N subportions are sequentially increased, to ensure the structure to be more stable.

In one embodiment, after Step S3, the method may also include:

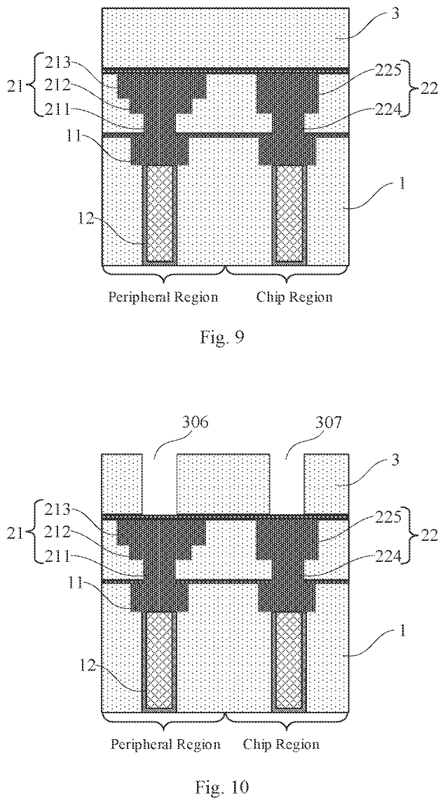

S4: forming a second dielectric layer 3 on the first dielectric layer 2, as shown in FIG. 9.

In one embodiment, the second dielectric layer 3 is a single-layer structure. In other embodiments, the second dielectric layer 3 may also be a stacked-layer structure. This embodiment does not limit the structure and arrangement of the second dielectric layer 3. In one embodiment, the second dielectric layer 3 may include one or more of a silicon nitride layer, a silicon oxide layer, and so on. This embodiment does not limit the material of the second dielectric layer 3. In some embodiments, in one embodiment, the second dielectric layer 3 may be the silicon nitride layer and the silicon oxide layer stacked sequentially from bottom to top.

In one embodiment, after Step S4, the method may further comprise:

S5: forming, on the second dielectric layer 3, a fourth mask layer having a sixth opening pattern and a seventh opening pattern, wherein the sixth opening pattern and the seventh opening pattern are positioned in the peripheral region and the chip region, respectively; and

S6: etching the second dielectric layer 3 by means of the sixth opening pattern and the seventh opening pattern to form a sixth opening 306 and a seventh opening 307 respectively in the second dielectric layer 3, as shown in FIG. 10, wherein the sixth opening 306 and the seventh opening 307 are positioned in the peripheral region and the chip region, respectively.

In one embodiment, after Step S6, the method may further include:

S7: forming a top-layer interconnection structure 31 in the sixth opening 306 and the seventh opening 307, as shown in FIG. 11.

In one embodiment, the top-layer interconnection structure 31 may be a single-layer structure, a stacked-layer structure, or other structure, and this embodiment does not limit the structure and arrangement of the top-layer interconnection structure 31. In one embodiment, a material of the top-layer interconnection structure 31 may include one or more of aluminum, titanium, titanium nitride, or tungsten, etc. However, this embodiment does not limit the material of the top-layer interconnection structure 31. In one embodiment, the top-layer interconnection structure 31 includes a titanium layer and a tungsten layer stacked sequentially from bottom to top.

In one embodiment, after Step S7, the method may further comprise:

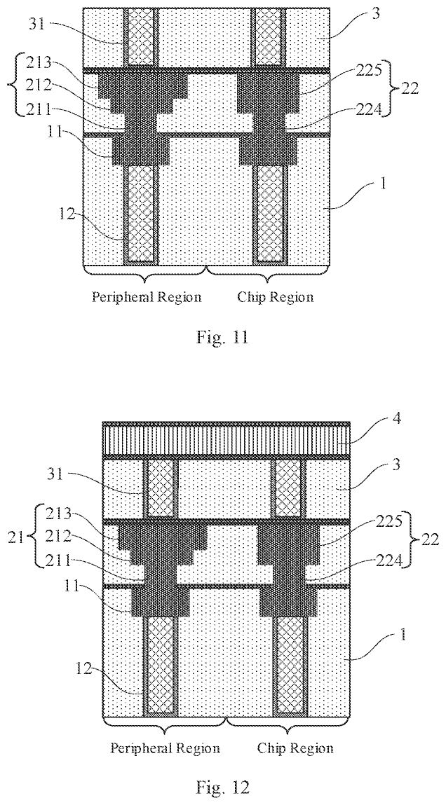

S8: forming a top-layer metal material layer 4 on the second dielectric layer 3, as shown in FIG. 12.

In one embodiment, the top-layer metal material layer 4 formed is a single-layer structure or a stacked-layer structure, and this embodiment does not limit the structure and arrangement of the top-layer metal material layer 4. In one embodiment, the top-layer metal material layer 4 may comprise a stacked-layer structure where the titanium layer and the aluminum layer are alternately stacked in sequence or a stacked-layer structure where the titanium nitride layer and the aluminum layer are alternately stacked in sequence, and a bottom layer and a top layer of the top-layer metal material layer are both the titanium layers or the titanium nitride layers.

In one embodiment, after Step S8, the method may further comprise:

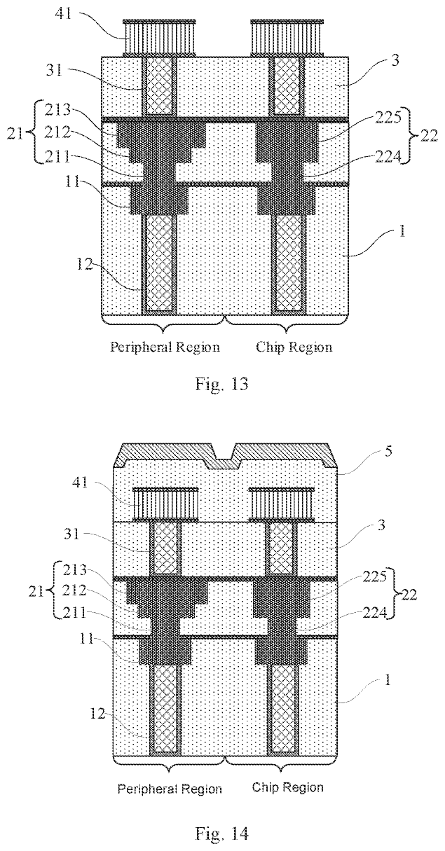

S9: etching the top-layer metal material layer 4 to form a top-layer metal layer 41 and expose a portion of the second dielectric layer 3, as shown in FIG. 13.

In one embodiment, after Step S9, the method may further comprise:

S10: forming a top-layer dielectric layer 5 over the second dielectric layer 3 and the top-layer metal layer 41, as shown in FIG. 14.

In one embodiment, the top-layer dielectric layer 5 formed may be a single-layer structure or a stacked-layer structure, and this embodiment does not limit the structure of the top-layer dielectric layer 5. In some embodiments, in one embodiment, the top-layer dielectric layer 5 may be a silicon oxide layer and a silicon nitride layer stacked sequentially from bottom to top.

It should be understood that although the steps in the flow diagrams of FIG. 1 and FIG. 4 are shown sequentially as indicated by the arrows, these steps are not necessarily performed sequentially in the order indicated by the arrows. It should be understood that unless expressly stated herein, the execution of these steps is not strictly limited in sequence, and these steps may be performed in other orders. Moreover, at least some of the steps in FIG. 1 and FIG. 4 may include a plurality of steps or a plurality of stages, which are not necessarily performed at the same moment, but may be executed at different moments, and the order of execution of these steps or stages is not necessarily performed sequentially, but may be performed alternately or alternately with at least a portion of the steps or stages of other steps or other steps.

With continued reference to FIG. 8, the present disclosure provides a semiconductor structure, comprising:

a substrate, the substrate comprising a peripheral region and a chip region;

a first dielectric layer 2 arranged on the peripheral region and the chip region of the substrate; and

a protective structure 21 and a functional structure 22 in the first dielectric layer 2 on the peripheral region and in the first dielectric layer 2 on the chip region, respectively.

The protective structure 21 comprises a first subportion 211, a second subportion 212 and a third subportion 213 stacked in sequence. The functional structure 22 comprises a fourth subportion 224 and a fifth subportion 225 stacked in sequence. A total height of the first subportion 211, the second subportion 212 and the third subportion 213 is equal to a total height of the fourth subportion 224 and the fifth subportion 225.

The semiconductor structure provided by the above embodiment has a more stable structure, has a larger interception area, and provides better protection to a chip.

In one embodiment, the substrate may include, but is not limited to, a silicon substrate. In other embodiments, the substrate may also be a gallium nitride substrate, an indium phosphide substrate, or a sapphire substrate, etc.

In one embodiment, the bottom-layer dielectric layer 1 is formed on the substrate, the first dielectric layer 2 is formed on the peripheral region and the chip region of the bottom-layer dielectric layer 1, and the bottom-layer metal layer 11 and the interconnection structure 12 are formed in the bottom-layer dielectric layer 1. In some embodiments, in one embodiment, a through hole is respectively formed in the peripheral region and the chip region of the bottom-layer dielectric layer 1, and the interconnection structure 12 and the bottom-layer metal layer 11 are stacked sequentially from bottom to top in the through hole.

In one embodiment, the interconnection structure 12 may be a single-layer structure or a stacked-layer structure, and this embodiment does not limit the structure of the interconnection structure 12. In one embodiment, a material of the interconnection structure 12 may include one or more of titanium, titanium nitride, or tungsten, etc. This embodiment does not limit the material of the interconnection structure 12. In one embodiment, the interconnection structure 12 comprises a conductive metal and a barrier layer, wherein the conductive metal comprises tungsten, ruthenium, and the like, and the barrier layer comprises titanium nitride, titanium, and the like.

In one embodiment, the first dielectric layer 2 is a single-layer structure. In other embodiments, the first dielectric layer 2 may also be a stacked-layer structure. This embodiment does not limit the structure and arrangement of the first dielectric layer 2. In one embodiment, the first dielectric layer 2 may include one or more of a silicon nitride layer, a silicon oxide layer, and so on. This embodiment does not limit the material of the first dielectric layer 2. In some embodiments, in one embodiment, the first dielectric layer 2 may be the silicon nitride layer and the silicon oxide layer stacked sequentially from bottom to top, and the protective structure 21 formed is positioned in the silicon oxide layer.

In one embodiment, the width of the second subportion 212 is greater than that of the first subportion 211, and the width of the third subportion 213 is greater than that of the second subportion 212.

In one embodiment, the width of the first subportion 211 is the same as that of the fourth subportion 224, and the width of the second subportion 212 is the same as that of the fifth subportion 225.

In one embodiment, the first subportion 211, the second subportion 212, and the third subportion 213 are integrally formed. The fourth subportion 224 and the fifth subportion 225 are integrally formed.

In one embodiment, the protective structure 21 includes N subportions stacked sequentially, wherein N is an integer greater than 3.

The semiconductor structure provided in the above embodiment has more subportions, which further increases the interception area and further enhances the protection of this structure for the chip.

In one embodiment, widths of the N subportions stacked in sequence are sequentially increased.

The semiconductor structure provided in the above embodiment has N subportions stacked in sequence, and the widths of the N subportions are sequentially increased, to ensure the structure to be more stable.

In some embodiments, in one embodiment, the first subportion 211, the second subportion 212, and the third subportion 213 are all annular wall structures. The fourth subportion 224 is a conductive plug structure, and the fifth subportion 225 is a conductive wire structure.

In one embodiment, the semiconductor structure further comprises a bottom metal layer positioned below the protective structure 21. In some embodiments, the material of the bottom-layer metal layer may include, but is not limited to, tungsten.

With continued reference to FIG. 9, in one embodiment, the semiconductor structure further comprises:

a second dielectric layer 3 arranged on the first dielectric layer 2.

In one embodiment, the second dielectric layer 3 is a single-layer structure. In other embodiments, the first dielectric layer 2 may also be a stacked-layer structure. This embodiment does not limit the structure and arrangement of the second dielectric layer 3. In one embodiment, the second dielectric layer 3 may include one or more of a silicon nitride layer, a silicon oxide layer, and so on. This embodiment does not limit the material of the second dielectric layer 3. In some embodiments, in one embodiment, the second dielectric layer 3 may be the silicon nitride layer and the silicon oxide layer stacked sequentially from bottom to top.

Referring to FIG. 11, in one embodiment, the semiconductor structure further comprises:

a sixth opening 306;

a seventh opening 307, both the sixth opening 306 and the seventh opening 307 being positioned in the second dielectric layer 3 and positioned in the peripheral region and the chip region, respectively; and

a top-layer interconnection structure 31 arranged in the sixth opening 306 and the seventh opening 307.

In one embodiment, the top-layer interconnection structure 31 may be a single-layer structure, a stacked-layer structure, or other structure, and this embodiment does not limit the structure and arrangement of the top-layer interconnection structure 31. In one embodiment, a material of the top-layer interconnection structure 31 may include one or more of titanium, titanium nitride, or tungsten, etc. However, this embodiment does not limit the material of the top-layer interconnection structure 31. In one embodiment, the top-layer interconnection structure 31 includes a titanium layer and a tungsten layer stacked sequentially from bottom to top.

With continued reference to FIG. 12, in one embodiment, the semiconductor structure further comprises:

a top-layer metal layer 41 arranged on an upper surface of the second dielectric layer 3.

In one embodiment, the top-layer metal layer 41 is a single-layer structure or a stacked-layer structure, and this embodiment does not limit the structure and arrangement of the top-layer metal layer 41. In one embodiment, the top-layer metal material layer 41 may comprise a stacked-layer structure where the titanium layer and the aluminum layer are alternately stacked in sequence or a stacked-layer structure where the titanium nitride layer and the aluminum layer are alternately stacked in sequence, and a bottom layer and a top layer of the top-layer metal material layer are both the titanium layers or the titanium nitride layers.

With continued reference to FIG. 14, in one embodiment, the semiconductor structure further comprises:

a top-layer dielectric layer 5 arranged on the upper surface of the second dielectric layer 3 and the upper surface of the top-layer metal layer 41.

In one embodiment, the top-layer dielectric layer 5 formed may be a single-layer structure or a stacked-layer structure, and this embodiment does not limit the structure of the top-layer dielectric layer 5. In some embodiments, in one embodiment, the top-layer dielectric layer 5 may be a silicon oxide layer and a silicon nitride layer stacked sequentially from bottom to top.

The semiconductor structure provided by the embodiments of the present disclosure has a more stable structure, has a larger interception area, and provides better protection to a chip.

The semiconductor structure formed by means of the method for fabricating a semiconductor structure provided in the embodiments of the present disclosure has a more stable structure, has a larger interception area, provides better protection to the chip, and has a simpler technological process.

Technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express a plurality of implementations of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be subject to the appended claims.

What is claimed is:

1. A semiconductor structure, comprising:
a substrate, the substrate comprising a peripheral region and a chip region;
a first dielectric layer positioned on the peripheral region and the chip region of the substrate; and
a protective structure and a functional structure respectively positioned in the first dielectric layer on the peripheral region and in the first dielectric layer on the chip region;
wherein the protective structure comprises a first subportion, a second subportion and a third subportion stacked in sequence, the functional structure comprising a fourth subportion and a fifth subportion stacked in sequence, a total height of the first subportion, the second subportion and the third subportion being equal to a total height of the fourth subportion and the fifth subportion.

2. The semiconductor structure according to claim 1, wherein
a width of the second subportion is greater than that of the first subportion; and
a width of the third subportion is greater than the width of the second subportion.

3. The semiconductor structure according to claim 2, wherein
the width of the first subportion is equal to that of the fourth subportion; and
the width of the second subportion is equal to that of the fifth subportion.

4. The semiconductor structure according to claim 1, wherein
the first subportion, the second subportion and the third subportion are integrally formed; and
the fourth subportion and the fifth subportion are integrally formed.

5. The semiconductor structure according to claim 1, wherein
the first dielectric layer is a single-layer structure.

6. The semiconductor structure according to claim 1, wherein
the protective structure comprises N subportions stacked in sequence, the N being an integer greater than 3.

7. The semiconductor structure according to claim 6, wherein
widths of the N subportions stacked in sequence increase successively.

8. The semiconductor structure according to claim 1, wherein
the first subportion, the second subportion and the third subportion are all annular wall structures;
the fourth subportion is a conductive plug structure; and
the fifth subportion is a conductive wire structure.

9. The semiconductor structure according to claim 4, further comprising:
a bottom metal layer positioned below the protective structure and a top-layer interconnection structure positioned above the protective structure, respectively; wherein
a material of the protective structure comprises copper, a material of the bottom metal layer comprising tungsten, and a material of the top-layer interconnection structure comprising tungsten or aluminum.

10. A method for fabricating a semiconductor structure, comprising:
providing a substrate, the substrate comprising a peripheral region and a chip region;
forming a first dielectric layer on the peripheral region and the chip region of the substrate; and
forming a protective structure and a functional structure respectively in the first dielectric layer on the peripheral region and in the first dielectric layer on the chip region;
wherein the protective structure comprises a first subportion, a second subportion and a third subportion stacked in sequence, the functional structure comprising a fourth subportion and a fifth subportion stacked in sequence, a total height of the first subportion, the second subportion and the third subportion being equal to a total height of the fourth subportion and the fifth subportion.

11. The method for fabricating a semiconductor structure according to claim 10, wherein the forming a protective structure and a functional structure respectively in the first dielectric layer on the peripheral region and in the first dielectric layer on the chip region comprises:
forming, on the first dielectric layer, a first mask layer having a first opening pattern and a fourth opening pattern, the first opening pattern and the fourth opening pattern being positioned in the peripheral region and the chip region, respectively;
etching the first dielectric layer by means of the first opening pattern and the fourth opening pattern to respectively form a first opening and a fourth opening in the first dielectric layer;
removing the first mask layer and forming a first filling layer in the first opening and the fourth opening;
forming, on the first dielectric layer, a second mask layer having a second opening pattern and a fifth opening pattern, the second opening pattern and the fifth opening pattern respectively exposing the first filling layer in the first opening and the first filling layer in the fourth opening, a width of the second opening pattern being greater than that of the first opening, and a width of the fifth opening pattern being greater than that of the fourth opening;
etching the first dielectric layer by means of the second opening pattern and the fifth opening pattern to form a second opening and a fifth opening in the first dielectric layer, respectively;
removing the second mask layer and forming a second filling layer in the second opening and the fifth opening;
forming, on the first dielectric layer, a third mask layer having a third opening pattern, the third opening pattern exposing the second filling layer in the second opening, and a width of the third opening pattern being greater than that of the second opening;
etching the first dielectric layer by means of the third opening pattern to form a third opening in the first dielectric layer; and
simultaneously filling the first opening, the second opening, the third opening, the fourth opening and the fifth opening with an electrically conductive material to form the protective structure and the functional structure, respectively.

12. The method for fabricating a semiconductor structure according to claim 11, wherein
the width of the first opening is equal to the width of the fourth opening; and
the width of the second opening is equal to that of the fifth opening.

13. The method for fabricating a semiconductor structure according to claim 12, wherein
an opening depth of the first opening is equal to that of the fourth opening; and
an opening depth of the second opening is equal to that of the fifth opening.

14. The method for fabricating a semiconductor structure according to claim 10, wherein
the first dielectric layer formed is a single-layer structure; and
the protective structure formed comprises N subportions stacked in sequence, the N being an integer greater than 3.

15. The method for fabricating a semiconductor structure according to claim 14, wherein
widths of the N subportions stacked in sequence increase successively.
